(19) United States
(12) Patent Application Publication
(10) Pub. No.: US 2003/0118857 A1
(43) Pub. Date: Jun. 26, 2003

(54) Method for producing an electromagnetic shield

(76) Inventors: Helmut Kahl, Berlin (DE); Bernd Tiburtius, Kleinmachnow (DE)

Correspondence Address: Gottlieb Rackman & Reisman, 270 Madison Avenue, New York, NY, 10016-0601, US

(21) Appl. No.: 10/181,530

(22) PCT Filed: Jan. 22, 2001
(86) PCT No.: PCT/EP01/00671

(30) Foreign Application Priority Data
Jan. 22, 2000 (DE) 100 03 355.5

(51) Int. Cl. B32B 7/00

(52) U.S. Cl. 428/626; 156/310

(57) ABSTRACT

The invention concerns a method of making a mechanical and electrically conductive connection between a printed circuit board or a housing portion and an electrically conductive covering (metal cap) for electromagnetic shielding.

Such—relatively rigid—metal caps are soldered by machine on to a printed circuit board for mechanical fixing thereof and, if the soldering operation is carried out satisfactorily, also afford a good shielding function. The high supply of heat which is to be applied in the soldering operation repeatedly gives rise to difficulties in regard to the mass production of the electrical components or the shielding thereof by means of the above-mentioned metal cap technology.

The object of the invention is to eliminate the above-mentioned disadvantages and to improve the previous production technology.

A method of making a connection between a printed circuit board and an electrically conductive cap for electromagnetic shielding, wherein arranged between the printed circuit board and the cap is an electrically conductive mass which is processable in the initial condition, preferably being a mass which is capable of flow, and by means of the electrically conductive mass the cap is fixed on the printed circuit board and at the same time electrical contacting is effected between the cap and the printed circuit board.

The invention concerns a method of making a mechanical and electrically conductive connection between a printed circuit board or a housing portion and an electrically conductive covering (metal cap) for electromagnetic shielding.

For the purposes of electromagnetically shielding components or structural groups, for example printed circuit boards or housings of mobile telephones (or in the telecommunication art or transmitting and/or receiving art), it is known to use metal caps which ensure at least partial shielding.

Such—relatively rigid—metal caps are soldered by machine on to a printed circuit board for mechanical fixing thereof and, if the soldering operation is carried out satisfactorily, also afford a good shielding function. The high supply of heat which is to be applied in the soldering operation repeatedly gives rise to difficulties in regard to the mass production of the electrical components or the shielding thereof by means of the above-mentioned metal cap technology.

The object of the invention is to eliminate the above-mentioned disadvantages and to improve the previous production technology.

The invention proposes applying to the printed circuit board (on the top side) or the electrically conductive cover, for example the metal cap (at the underside), an electrically conductive mass which in the initial condition is fluid or pasty. That mass can both comprise silicone, epoxy, PU, Teflon, acryl, EPDM, EPM or other bonding substances, and it may also contain an electrically conductive filler. That filler may contain both carbon, metal, aluminum, copper, silver, gold, for example in the form of fiber balls or strips. However multifunctional fillers such as for example silver-plated glass, copper, nickel, aluminum, nickel-plated graphite or the like are also suitable as the electrically conductive filler.

The electrically conductive mass which contains the electrically conductive filler can be applied to the printed circuit board or a lower housing portion or also to the electrically conductive covering by a dispensing procedure as is described for example in patent P 43 19 965.809. It is however also possible for the electrically conductive mass to be applied by a printing process, for example screen printing or stencil printing or by an immersion process (dipping) or molding out and so forth.

Insofar as reference is made to a metal cap in the present application, that also includes a cap of plastic material or another non-conducting material which is provided with a conductive layer, for example metallisation, or which has an electrically conductive layer at the inside in the material.

An electrically conductive mass such as for example silicone mixed with silver has the property of being self-sticking and also self-adhering so that, when the printed circuit board and the electrically conductive covering (shielding cap, metal cap) are brought together, it is possible to produce a durable connection—if desired however, also releasable—between those two components. That connection can be still further enhanced, initiated or concluded by a hardening process, a drying process, a cross-linking process, for example by means of heat radiation (or other energy irradiation), alpha radiation, beta radiation, gamma radiation, light, UV-radiation, IR-radiation or in a special air humidity environment. In that respect in particular such conditions are advantageous for cross-linking or drying or hardening of the electrically conductive mass, which can be carried into effect at markedly lower temperatures than for example when using soldering.

The invention provides that for example equipping the printed circuit boards by means of metal caps can be automatically carried out at an SMD (Surface Mounting Device) fitting station. That prevents displacement of the shielding cap without a substantial supply of heat occurring, as in the soldering process. That means that the shielding cap is not only electrically connected to the printed circuit board but it is also fixed, arrested or held mechanically at its predetermined position.

The invention is described in greater detail hereinafter by means of an embodiment illustrated in the drawing in which:

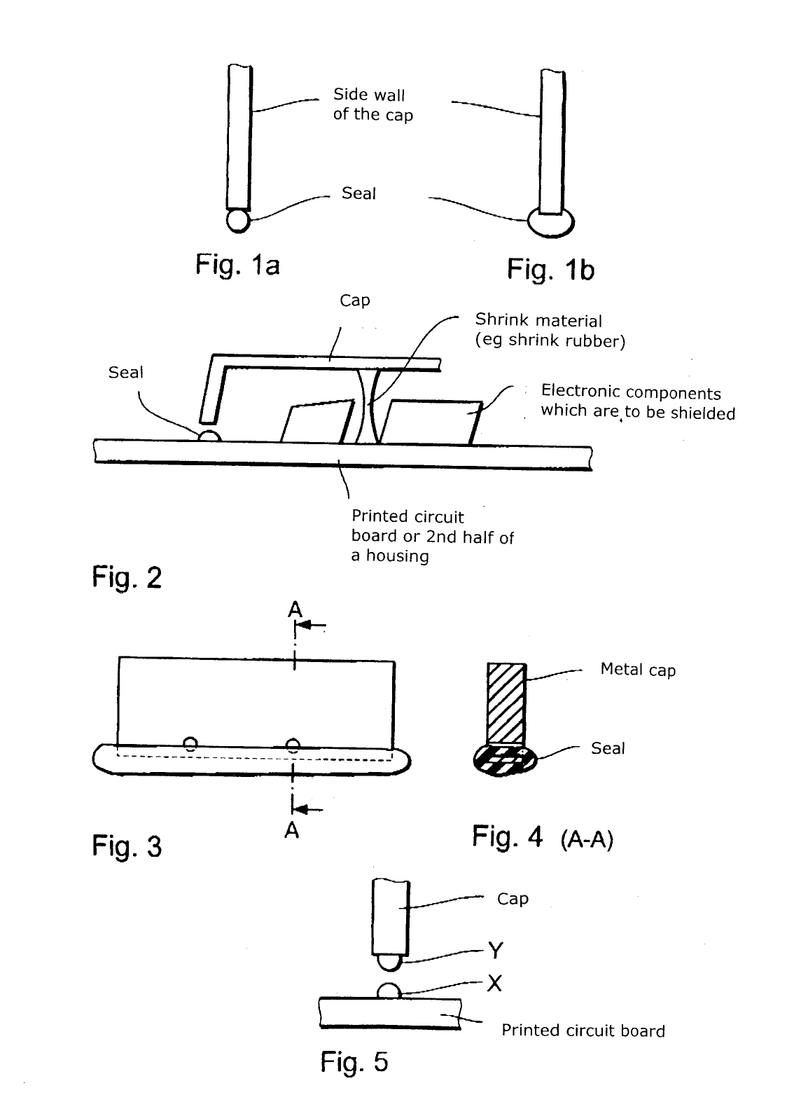

FIG. 1 is a cross-section of a side wall of a shielding cap, below which is arranged a bead of an electrically conductive mass,

FIG. 2 shows a cross-section of a printed circuit board with electrical components and the cap fitted thereto,

FIG. 3 shows a side view of the side wall of the fitted shielding cap,

FIG. 4 shows a cross-section through the view in FIG. 3 along AA, and

FIG. 5 shows a cross-section through a further configuration according to the invention.

In FIG. 1a a single-bead electrically conductive mass is applied (dispensed or dipped or hot-shaped or cold-shaped thereon) at the underside of the side wall of a metal cap (shielding cap). As shown in FIG. 1b the electrically conductive mass extends around the lower edge region of the side wall of the metal cap fitted on a printed circuit board or a housing.

FIG. 2 shows a printed circuit board with electrical components which are to be shielded and a seal which is applied to the printed circuit board and on to which the shielding cap shown in FIG. 1 is fitted. In this case the electrically conductive mass—the seal—is applied in the form of a bead to the top side of the printed circuit board. The properties of the seal in terms of conductivity, elasticity, thixotropy, hardness, releasability and so forth can be individually adjusted or can also be such as are described in DE P 43 19 965.8-09.

Insofar as a single bead of the electrically conductive mass is shown in the Figures, this may also involve beads/layers which are disposed in a plurality in superposed relationship and/or juxtaposed relationship and which are applied to the respective surface in a (dispensing) procedure (or a plurality of dispensing procedures and/or dipping one or more times or by shaping steps). It is also possible for example to apply at least one bead (layer) of electrically conductive mass to the top side of the printed circuit board and to the corresponding underside of the side wall of the shielding cap and then to connect the two parts by the superimposition of the two beads (layers).

In that respect it is particularly advantageous—see FIG. 5—if the layer (bead) applied to the printed circuit board serves as a reagent of a first component X of a two-component connection X-Y and the layer (bead) applied to the underside of the side wall of the shielding cap serves as a second component Y, which reacts to the reagent, of the two-component connection X-Y. The two components X and Y comprise different substances and react only when they are brought together, for example by being positioned one over the other. In that situation the two layers (beads) are connected together like a two- (or three- or multi-) component adhesive so that, besides the electrical connection, this also affords a very good mechanical connection between the cap and the printed circuit board (lower bottom part of the housing), which also withstands high tensile forces.

The above-described configuration of a two-component seal means that manufacture of the entire seal is a simple matter because the operation of producing the seal can be carried out in time-independent and non-critical fashion. Thus for example the layer applied to the printed circuit board can be applied first without the metal cap with the second component having to be fitted immediately. It is quite possible that the displacement in respect of time of the step of applying the individual layers (beads) and the step of assembling the printed circuit board and the shielding cap can be different from several seconds to several hours (or several days or weeks), depending on what the materials of the components X and Y are. The X-component moreover also does not have to be an electrically conductive mass but the layer with the X-(Y-)component can be very thin and can more or less dissolve when coming together with the Y-(X-)component so that then the bead comprising the Y-(X-) component mechanically fixes and provides for through contacting of the metal cap and the subjacent printed circuit board (or the housing therebeneath).

The above-described embodiment has the advantage that the layer with the X-component can already be applied to the locations which are to involve through-contacting, in the operation of producing the printed circuit board. If, for connecting the two layers of the X-Y-component, it should be necessary that in that case there must be a certain atmosphere (for example a moist atmosphere or a solvent-filled atmosphere), that aspect can be taken into consideration when applying the metal cap to the printed circuit board.

FIG. 3 shows a side view illustrating the side wall of the shielding cap shown in FIG. 1 and below that side wall the seal, produced from the electrically conductive mass.

FIG. 4 shows a view in cross-section through the view of FIG. 3. It can be seen in this respect that the lower edge of the metal cap is completely immersed in the seal material and even the opening shown in FIG. 3 of the side wall is in part filled with sealing material.

By virtue of the self-adhering or self-sticking properties of the conductive sealing mass, not only is an electrically conductive connection made between the shielding cap and the printed circuit board (housing portion), but also the two parts are mechanically sufficiently firmly connected together, while the elasticity of the conductive mass means that there is also still a certain degree of elasticity of the cap.

It will be appreciated that the illustrated connection between the shielding cap and the printed circuit board can also be made by the electrically conductive material not just being dispensed, but applied using a different application procedure, for example stencil printing.

It is also possible to apply to the top side of the cap still a further layer of the electrically conductive mass (a bead or a plurality of beads), which can be particularly advantageous if relatively large tolerances are to be admitted and the shielding cap is to be covered on the top side by a housing or another electrically conductive component.

The apparatuses which are provided with the above-described shielding may involve in particular those which have a transmitting device and/or a receiving device, for example a mobile telephone, or also a base station of a telecommunication network.

It is also possible for a strand or elongate portion (or a plurality of such portions) of a shrink material (for example shrink rubber, bonded to cap and printed circuit board) to be arranged between the shielding cap and the substrate to be shielded, for example the printed circuit board. This is shown by way of example in the middle of FIG. 2. If that material is subjected to a shrinkage process, it contracts and in so doing automatically bonds the two parts together more than previously, because the material is fixedly adhered both to the inside of the cap and also to the printed circuit board. In FIG. 2 the strand or elongate portion (of concave cross-sectional shape) of the shrink material is shown as an example.

1. A method of making a connection between a printed circuit board and an electrically conductive cap for electromagnetic shielding, wherein arranged between the printed circuit board and the cap is an electrically conductive mass which is processable in the initial condition, and by means of the electrically conductive mass the cap is fixed on the printed circuit board and at the same time electrical contacting is effected between the cap and the printed circuit board, wherein the electrically conductive mass comprises two different components (X, Y) and before the cap and the printed circuit board are assembled both the cap and also the printed circuit board are provided at the mutually facing locations with a suitable material layer of one of the two components so that the cap and also the printed circuit board are provided with different material layers and the two layers are connected when the cap is assembled to the printed circuit board and react with each other like a two-component adhesive.

1. A method of making a connection between a printed circuit board and an electrically conductive cap for electromagnetic shielding, wherein arranged between the printed circuit board and the cap is an electrically conductive mass which is processable in the initial condition, preferably being a mass which is capable of flow, and by means of the electrically conductive mass the cap is fixed on the printed circuit board and at the same time electrical contacting is effected between the cap and the printed circuit board.

2. A method as set forth in claim 1 characterised in that the method is carried out for automatically fitting the printed circuit board with the cap.

3. A method as set forth in claim 1 or claim 2 characterised in that the method for automatically fitting the printed circuit board with a cap is carried out at an SMD fitting station.

4. A method as set forth in one of the preceding claims characterised in that the conductive mass includes a silicone, epoxy, PU, Teflon, acryl, EPDM, EPM or other bonding substances or a mixture thereof and has an electrically conductive filler.

5. A method as set forth in claim 4 characterised in that the filler comprises carbon, metal, fiber balls of metal, for example aluminum, copper, silver, gold or multi-functional fillers such as for example silver-plated glass, copper, nickel, aluminum or nickel-plated graphite or the like.

6. A method as set forth in one of the preceding claims characterised in that the cap for shielding purposes is a metal cap or a metallised cap or a cover comprising non-conducting material, for example plastic material.

7. A method as set forth in one of the preceding claims characterised in that the electrically conductive mass is applied to the appropriate locations on the printed circuit board so that then the shielding cap is fitted on to the locations at which the electrically conductive mass is applied to the printed circuit board.

8. A method as set forth in one of claims 1 through 7 characterised in that application of the electrically conductive mass to the printed circuit board or however also the cap is effected by an application process, for example a dispensing process, a printing process, a stencil printing process, a screen printing process, immersion, dipping, or a tampon printing process (molding thereon).

9. A method as set forth in one of the preceding claims characterised in that after the connection between the printed circuit board and the cap has been made with the electrically conductive mass, a durable connection between those components is made, with the mass being solidified and/or cross-linked and/or dried.

10. A method as set forth in claim 9 characterised in that the durable connection is effected by a hardening process, for which purpose treatment is effected by means for example of heat and/or alpha rays and/or beta rays and/or gamma rays and/or air humidity and/or light and/or ultraviolet light and/or infrared radiation.

11. A method as set forth in one of the preceding claims characterised in that the temperature in the hardening process is markedly lower than the temperatures which usually occur in the soldering procedure for connecting the cap to the printed circuit board.

12. Connecting an electrically conductive cap to a printed circuit board by means of a method as set forth in one of the preceding claims.

13. A printed circuit board on which there is arranged an electrically conductive cap which has the function of a shielding element for components arranged on the printed circuit board, wherein an electrically conductive mass is provided for mechanical positioning of the cap between the printed circuit board and the cap, said electrically conductive mass making an electrically conducting connection between the printed circuit board and the metal cap.

14. A printed circuit board as set forth in claim 13 characterised in that the cap is arranged at a predetermined spacing relative to the printed circuit board and the spaced space between the cap and the printed circuit board is filled by the electrically conductive mass.

15. An electrical apparatus including a printed circuit board as set forth in one of the preceding claims.

16. An electrical apparatus as set forth in claim 15 characterised in that the electrical apparatus has at least a transmitting device and/or receiving device.

17. Apparatus as set forth in claim 16 characterised in that the electrical apparatus is a mobile radio unit.

18. A method as set forth in one of the preceding claims characterised in that for flexing and electrical contacting between the cap and the printed circuit board, a layer with a component X is applied to the printed circuit board and a layer with a component Y is applied to the underside of a side wall of a cap, wherein the two components are such that they react with each other (chemically, physically) so that the desired mechanical fixing and electrical contacting of the cap on the printed circuit board is guaranteed.

19. A method as set forth in one of the preceding claims characterised in that arranged between the shielding cap and the substrate to be shielded, for example the printed circuit board, is a shrinkable material which upon shrinkage fixes or pulls together the shielding cap and the substrate beneath the shielding cap (FIG. 2).
